(19) United States
(12) Patent Application Publication
(10) Pub. No.: US 2025/0046585 A1
(43) Pub. Date: Feb. 6, 2025

(54) SUBSTRATE PROCESSING SYSTEM AND TRANSFER METHOD

(71) Applicant: Tokyo Electron Limited, Tokyo (JP)

(72) Inventors: Tatsuru OKAMURA, Miyagi (JP); Masatomo KITA, Miyagi (JP); Young tae SONG, Miyagi (JP)

(73) Assignee: Tokyo Electron Limited, Tokyo (JP)

(21) Appl. No.: 18/926,710

(22) Filed: Oct. 25, 2024

Related U.S. Application Data
(63) Continuation of application No. PCT/JP2023/034678, filed on Sep. 25, 2023.

(30) Foreign Application Priority Data
Sep. 30, 2022 (JP) 2022-157525

(51) Int. Cl. H01J 37/32

(52) U.S. Cl. CPC H01J 37/32853; H01J 37/32642; H01J 37/32715; H01J 37/32807; H01J 37/32816; H01J 37/32889

(57) ABSTRACT

A substrate processing system according to an aspect of the present disclosure includes: a plurality of processors each including a substrate support supporting a substrate and a ring disposed around the substrate, a vacuum transferer connected to the processors, the vacuum transferer including a transfer robot for transferring the substrate or the ring, an accommodation for accommodating the ring, and a controller for executing control to remove all the substrates from the processors and the vacuum transferer, and after the removing, for executing control to transfer the ring between at least one of the processors and the accommodation.

### CROSS-REFERENCE TO RELATED APPLICATIONS

This application is a bypass continuation application of international application No. PCT/JP2023/034678 having an international filing date of Sep. 25, 2023 and designating the United States, the international application being based upon and claiming the benefit of priority from Japanese Patent Application No. 2022-157525, filed on Sep. 30, 2022, the entire contents of each are incorporated herein by reference in their entirety.

### TECHNICAL FIELD

The present disclosure relates to a substrate processing system and a transfer method.

### BACKGROUND

For example, Patent Document 1 proposes a method of replacing a ring assembly that surrounds a substrate that is supported by a substrate support in a plasma processing apparatus that performs plasma processing on the substrate.

### CITATION LIST

### Patent Documents

Patent Document 1: JP2018-010992A

### SUMMARY

The present disclosure provides a technique capable of reducing contamination of a substrate.

A substrate processing system according to an aspect of the present disclosure includes: a plurality of processors each including a substrate support supporting a substrate and a ring disposed around the substrate, a vacuum transfer unit (transferer) connected to the processors, the vacuum transfer unit including a transfer robot configured to transfer the substrate or the ring, an accommodation configured to accommodate the ring, and a controller configured to execute control to remove all the substrates from the processors and the vacuum transfer unit, and after the removing, configured to execute control to transfer the ring between at least one of the processors and the accommodation.

According to the present disclosure, it is possible to reduce contamination of the substrate.

### BRIEF DESCRIPTION OF DRAWINGS

FIG. 1 is a diagram illustrating an example of a substrate processing system according to an embodiment;

FIG. 2 is a schematic cross-sectional view illustrating an example of a ring accommodation;

FIG. 3 is a schematic cross-sectional view illustrating an example of a plasma processing apparatus;

FIG. 4 is an enlarged view of a portion in FIG. 3;

FIG. 5 is a schematic cross-sectional view illustrating another example of the plasma processing apparatus;

FIG. 6 is a flowchart illustrating a transfer method according to a first example of the embodiment;

FIG. 7 is a flowchart illustrating a transfer method according to a second example of the embodiment;

FIG. 8 is a flowchart illustrating a transfer method according to a third example of the embodiment;

FIG. 9 is a flowchart illustrating a transfer method according to a fourth example of the embodiment; and

FIG. 10 is a flowchart illustrating a transfer method according to a fifth example of the embodiment.

### DETAILED DESCRIPTION

Hereinafter, embodiments for implementing the present disclosure will be described with reference to the drawings. In the respective drawings, the same components will be denoted by the same reference numerals, and overlapping descriptions thereof may be appropriately omitted.

### Substrate Processing System

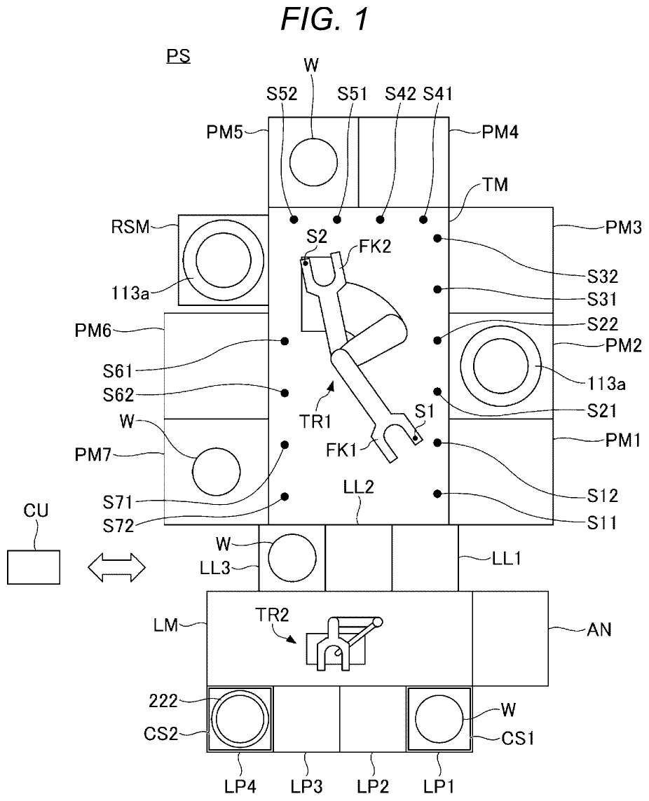

A substrate processing system PS according to an embodiment will be described with reference to FIG. 1. FIG. 1 is a diagram illustrating an example of the substrate processing system PS according to the embodiment. As illustrated in FIG. 1, the substrate processing system PS is a system capable of performing various types of processing, such as plasma processing, on a substrate W. The substrate W may be, for example, a semiconductor wafer.

The substrate processing system PS includes a vacuum transfer unit (i.e., transferer) TM, a plurality of processors PM1 to PM7, a ring accommodation RSM, a plurality of vacuum reserve units LL1 to LL3, an atmospheric transfer unit (i.e., transferer) LM, load ports LP1 to LP4, an aligner AN, and a controller CU. The vacuum transfer unit TM is also referred to as a transfer module. The processors PM1 to PM7 are also referred to as process modules. The ring accommodation RSM is also referred to as a ring stocker module. The vacuum reserve units LL1 to LL3 are also referred to as a load-lock module. The atmospheric transfer unit LM is also referred to as a loader module.

The vacuum transfer unit TM has a square shape in a plan view. The processors PM1 to PM7, the vacuum reserve units LL1 to LL3, and the ring accommodation RSM are connected to the vacuum transfer unit TM. The vacuum transfer unit TM has a vacuum transfer chamber. The vacuum transfer chamber is held in a vacuum atmosphere. A vacuum transfer robot TR1 is provided inside the vacuum transfer chamber.

The vacuum transfer robot TR1 is configured to be rotatable, extensible, and movable vertically. The vacuum transfer robot TR1 includes an upper fork FK1 and a lower fork FK2. The vacuum transfer robot TR1 holds and transfers the substrate W, an inner ring 113a, an outer ring 113b, a lower ring 221, and an upper ring 222 by the upper fork FK1 and the lower fork FK2. The vacuum transfer robot TR1 holds and transfers the substrate W, the inner ring 113a, the outer ring 113b, the lower ring 221, and the upper ring 222 between the processors PM1 to PM7, the vacuum reserve units LL1 to LL3, and the ring accommodation RSM. The upper fork FK1 is provided with a position detection sensor S1. The lower fork FK2 is provided with a position detection sensor S2. The position detection sensors S1 and S2 detect positions of the inner ring 113a, the outer ring 113b, the lower ring 221, and the upper ring 222 provided in the processors PM1 to PM7. The position detection sensors S1 and S2 may be, for example, optical sensors or cameras. The inner ring 113a, the outer ring 113b, the lower ring 221, and the upper ring 222 will be described later.

The vacuum transfer unit TM may be provided with position detection sensors S11 and S12. The position detection sensors S11 and S12 are provided on a transfer path of the substrate W and the inner ring 113a transferred from the vacuum transfer unit TM to the processor PM1. The position detection sensors S11 and S12 are used to correct positions of the substrate W and the inner ring 113a transferred from the vacuum transfer unit TM to the processor PM1. The position detection sensors S11 and S12 are provided, for example, in the vicinity of a gate valve (not shown) that separates the vacuum transfer unit TM and the processor PM1. The position detection sensors S11 and S12 are disposed, for example, such that their distances from each other are smaller than an outer diameter of the substrate W and smaller than an inner diameter of the inner ring 113a. Similar to the position detection sensors S11 and S12, the vacuum transfer unit TM may include position detection sensors S21, S22, S31, S32, S41, S42, S51, S52, S61, S62, S71, and S72.

The processors PM1 to PM7 are connected to the vacuum transfer unit TM. The processors PM1 to PM7 have vacuum processing chambers. A substrate support (not shown) is provided inside the vacuum processing chamber. In the processors PM1 to PM7, after the substrate W is placed on the substrate support, an inside of the processors PM1 to PM7 is depressurized, a processing gas is introduced, RF power is applied to generate plasma, and plasma processing is performed on the substrate W by the plasma. The vacuum transfer unit TM and the processors PM1 to PM7 are separated by a gate valve that can be opened and closed freely (not shown). The inner ring 113a and the outer ring 113b are disposed on the substrate support, for example. The lower ring 221 and the upper ring 222 may be disposed on the substrate support.

The ring accommodation RSM is connected to the vacuum transfer unit TM. The ring accommodation RSM is configured to accommodate, for example, the inner ring 113a and the outer ring 113b. The ring accommodation RSM may be configured to accommodate only the inner ring 113a. The ring accommodation RSM may be configured to accommodate only the outer ring 113b. The ring accommodation RSM will be described in detail later. The inner ring 113a and the outer ring 113b are transferred between the processors PM1 to PM7 and the ring accommodation RSM by the vacuum transfer robot TR1. The vacuum transfer unit TM and the ring accommodation RSM are separated by a gate valve that can be opened and closed freely (not shown). The ring accommodation RSM is an example of an accommodation.

The vacuum reserve units LL1 to LL3 are provided between the vacuum transfer unit TM and the atmospheric transfer unit LM. The vacuum reserve units LL1 to LL3 are connected to the vacuum transfer unit TM and the atmospheric transfer unit LM. The vacuum reserve units LL1 to LL3 have an internal pressure variable chamber of which an inside can be switched between vacuum and atmospheric pressure. A stage is provided inside the internal pressure variable chamber. The stage is configured such that the substrate W, the lower ring 221, and the upper ring 222 are placed thereon. When transferring the substrate W from the atmospheric transfer unit LM to the vacuum transfer unit TM, the vacuum reserve units LL1 to LL3 receive the substrate W from the atmospheric transfer unit LM while maintaining an inside at the atmospheric pressure, and the inside of the vacuum reserve units LL1 to LL3 is depressurized to transfer the substrate W to the vacuum transfer unit TM. When transferring the substrate W from the vacuum transfer unit TM to the atmospheric transfer unit LM, the vacuum reserve units LL1 to LL3 receive the substrate W from the vacuum transfer unit TM while maintaining the inside in a vacuum state, and the inside of the vacuum reserve units LL1 to LL3 is pressurized to the atmospheric pressure to transfer the substrate W to the atmospheric transfer unit LM. A case of transferring the lower ring 221 and the upper ring 222 may be similar to a case of transferring the substrate W. The vacuum reserve units LL1 to LL3 and the vacuum transfer unit TM are separated by a gate valve that can be opened and closed freely (not shown). The vacuum reserve units LL1 to LL3 and the atmospheric transfer unit LM are separated by a gate valve that can be opened and closed freely (not shown).

The atmospheric transfer unit LM faces the vacuum transfer unit TM. The atmospheric transfer unit LM may be, for example, an equipment front end module (EFEM). The atmospheric transfer unit LM has a square shape in the plan view. The atmospheric transfer unit LM has an atmospheric transfer chamber. An inside of the atmospheric transfer chamber is held in an atmospheric pressure atmosphere. An atmospheric transfer robot TR2 is provided inside the atmospheric transfer chamber. The atmospheric transfer robot TR2 holds and transfers the substrate W, the lower ring 221, and the upper ring 222 between the load ports LP1 to LP4, the aligner AN, and the vacuum reserve units LL1 to LL3. The atmospheric transfer unit LM may have a fan filter unit (FFU).

The load ports LP1 to LP4 are connected to the atmospheric transfer unit LM. Various containers are placed in the load ports LP1 to LP4. The various containers may include a substrate accommodation container CS1 and a ring accommodation container CS2. The substrate accommodation container CS1 may be, for example, a front-opening unified pod (FOUP) that accommodates a plurality (for example, 25) substrates W. The ring accommodation container CS2 may be, for example, a container that accommodates a plurality of lower rings 221 and upper rings 222. A ring accommodation shelf may be provided inside the atmospheric transfer chamber, and the ring accommodation shelf may be configured to accommodate the lower rings 221 and upper rings 222. The ring accommodation container CS2 and the ring accommodation shelf are examples of the accommodation. In the example in FIG. 1, the substrate accommodation container CS1 is placed in the load port LP1, and the ring accommodation container CS2 is placed in the load port LP4.

The aligner AN is connected to the atmospheric transfer unit LM. The aligner AN is configured to adjust a position of the substrate W. The aligner AN may be configured to adjust positions of the lower ring 221 and the upper ring 222. The aligner AN may be provided inside the atmospheric transfer chamber.

The controller CU controls each part of the substrate processing system PS. The controller CU controls, for example, an operation of the vacuum transfer robot TR1, an operation of the atmospheric transfer robot TR2, and opening and closing of the gate valve. The controller CU may be, for example, a computer. The controller CU includes a central processing unit (CPU), a random access memory (RAM), a read only memory (ROM), an auxiliary storage device, and the like. The CPU operates based on a program stored in the ROM or the auxiliary storage device, and controls each part of the substrate processing system PS.

### Ring Accommodation

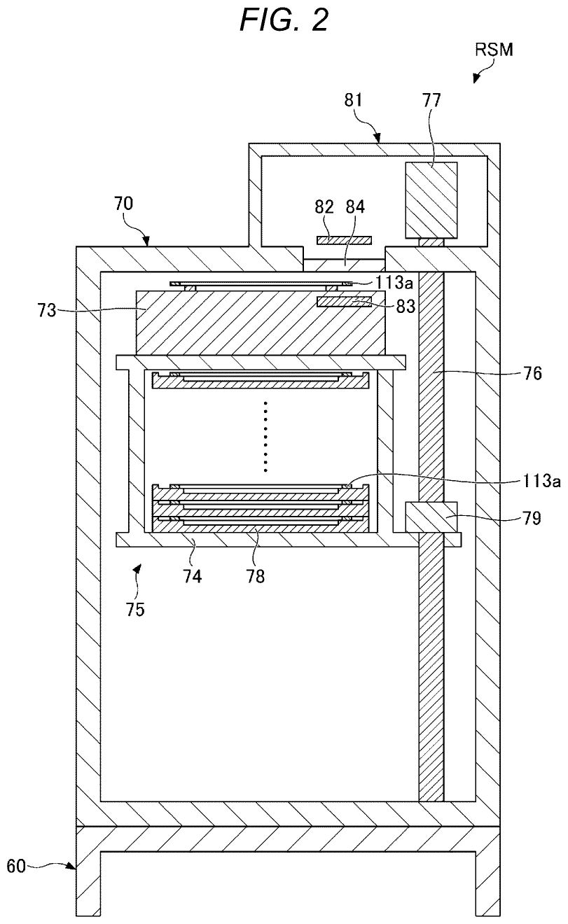

The ring accommodation RSM will be described with reference to FIG. 2. FIG. 2 is a schematic cross-sectional view illustrating an example of the ring accommodation RSM.

The ring accommodation RSM has a chamber 70 disposed on a frame 60, and a machine chamber 81 disposed at an upper portion of the chamber 70. The chamber 70 is configured so that an inside can be depressurized. A nitrogen (N₂) gas, for example, is supplied as a purge gas into the chamber 70. Accordingly, a pressure in the chamber 70 can be adjusted. The machine chamber 81 has, for example, an atmospheric pressure atmosphere.

A storage 75 having a stage 73 and a basket 74 provided at a lower portion of the stage 73 is disposed in the chamber 70. The storage 75 is configured so as to be able to move up and down by a ball screw 76. A line sensor 82 that detects positions and directions of the inner ring 113a and the outer ring 113b, and a motor 77 that drives the ball screw 76 are disposed in the machine chamber 81. A window 84 made of quartz or the like is provided between the chamber 70 and the machine chamber 81 to allow the line sensor 82 to receive light from a light emitting unit 83 to be described later.

The inner ring 113a and the outer ring 113b are placed on the stage 73. In the example in FIG. 2, the inner ring 113a is placed on the stage 73. The stage 73 has the light emitting unit 83 that faces the line sensor 82. The stage 73 is rotatable about a rotation axis in a vertical direction, and rotates the placed inner ring 113a and outer ring 113b in a desired direction. That is, the stage 73 performs alignment of the inner ring 113a and the outer ring 113b. In the alignment, orientation flats (OFs) of the inner ring 113a and the outer ring 113b are aligned in a desired direction. In the alignment, center positions of the inner ring 113a and the outer ring 113b may be aligned.

The line sensor 82 detects an amount of light emitted from the light emitting unit 83, and outputs the detected amount of light to the controller CU. The controller CU detects the orientation flats of the inner ring 113a and the outer ring 113b by using the fact that the detected amount of light varies depending on presence or absence of the orientation flats of the inner ring 113a and the outer ring 113b. The controller CU detects directions of the inner ring 113a and the outer ring 113b based on the detected orientation flats. The line sensor 82 is, for example, a line sensor such as a charge coupled device (CCD) or a complementary metal oxide semiconductor (CMOS).

The basket 74 is provided at the lower portion of the stage 73. A cassette 78 is placed in the basket 74. The cassette 78 is an accommodation container that can be extracted from the basket 74. The cassette 78 accommodates the inner rings 113a and the outer rings 113b at intervals in an upper-lower direction. In the example in FIG. 2, the cassette 78 accommodates the inner rings 113a.

In addition to the stage 73 and the basket 74, the storage 75 has a guide 79 supported by the ball screw 76 on a side surface. The ball screw 76 connects an upper surface and a lower surface of the chamber 70, passes through the upper surface of the chamber 70, and is connected to the motor 77 in the machine chamber 81. A through-portion of the upper surface of the chamber 70 is sealed to allow the ball screw 76 to rotate. The ball screw 76 is rotated by the motor 77, thereby enabling the storage 75 to move in the upper-lower direction (a Z-axis direction).

The upper fork FK1 and the lower fork FK2 of the vacuum transfer robot TR1 can be inserted into the chamber 70. The upper fork FK1 and the lower fork FK2 load the inner ring 113a and the outer ring 113b into the cassette 78, and unload the inner ring 113a and the outer ring 113b placed in the cassette 78, for example. The upper fork FK1 and the lower fork FK2 place the inner ring 113a and the outer ring 113b on the stage 73, and acquire the inner ring 113a and the outer ring 113b placed on the stage 73, for example.

### Plasma Processing Apparatus

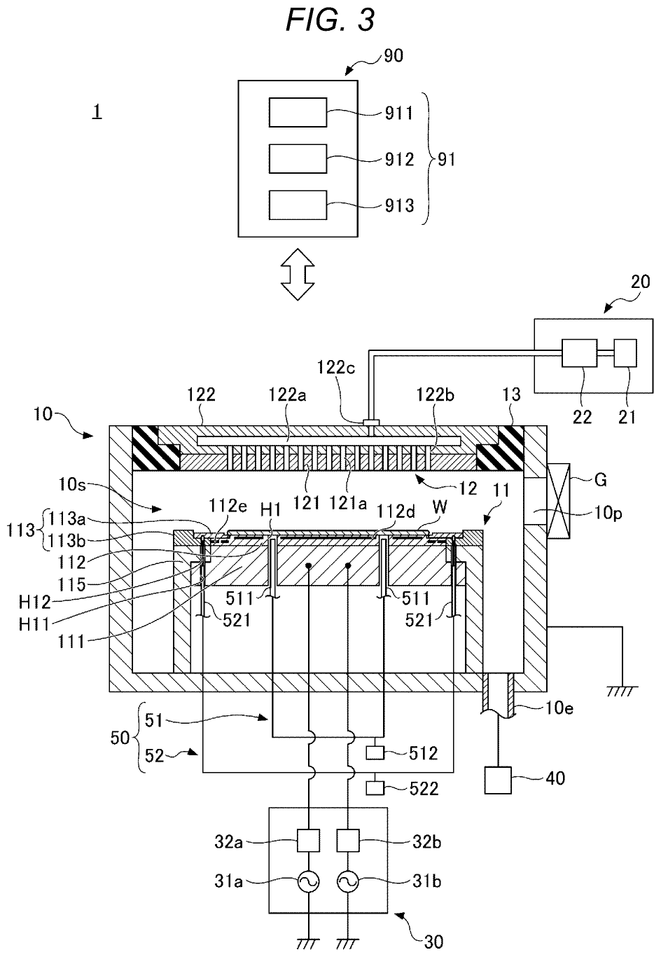

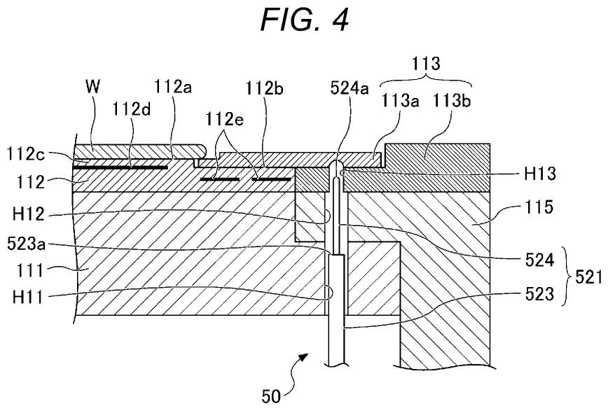

An example of a plasma processing apparatus that can be applied as the processors PM1 to PM7 illustrated in FIG. 1 will be described with reference to FIGS. 3 and 4. FIG. 3 is a schematic cross-sectional view illustrating an example of the plasma processing apparatus. FIG. 4 is an enlarged view of a portion in FIG. 3.

A plasma processing apparatus 1 includes a plasma processing chamber 10, a gas supply 20, an RF power supply 30, an exhaust system 40, a lifter 50, and a controller 90.

The plasma processing chamber 10 includes a substrate support 11 and an upper electrode 12. The substrate support 11 is disposed in a lower region of a plasma processing space 10s in the plasma processing chamber 10. The upper electrode 12 is disposed above the substrate support 11 and may function as a part of a top plate of the plasma processing chamber 10.

The substrate support 11 supports the substrate W in the plasma processing space 10s. The substrate support 11 includes a lower electrode 111, an electrostatic chuck 112, a ring assembly 113, and an insulating member 115.

The electrostatic chuck 112 is disposed on the lower electrode 111. The electrostatic chuck 112 has an upper surface that includes a substrate support surface 112a and a ring support surface 112b. The electrostatic chuck 112 supports the substrate W on the substrate support surface 112a. The electrostatic chuck 112 supports the inner ring 113a on the ring support surface 112b. The electrostatic chuck 112 includes an insulating member 112c, a first attraction electrode 112d, and a second attraction electrode 112e. The first attraction electrode 112d and the second attraction electrode 112e are embedded in the insulating member 112c. The first attraction electrode 112d is located below the substrate support surface 112a. The electrostatic chuck 112 attracts and holds the substrate W on the substrate support surface 112a by applying a voltage to the first attraction electrode 112d. The second attraction electrode 112e is located below the ring support surface 112b. The electrostatic chuck 112 attracts and holds the inner ring 113a on the ring support surface 112b by applying a voltage to the second attraction electrode 112e. In the examples in FIGS. 3 and 4, the electrostatic chuck 112 includes a unipolar electrostatic chuck that attracts and holds the substrate W, and a bipolar electrostatic chuck that attracts and holds the inner ring 113a. A bipolar electrostatic chuck may be used instead of the unipolar electrostatic chuck, and a unipolar electrostatic chuck may be used instead of the bipolar electrostatic chuck.

The ring assembly 113 includes the inner ring 113a and the outer ring 113b. The inner ring 113a has an annular shape. The inner ring 113a is disposed around the substrate W on an upper surface of a peripheral portion of the lower electrode 111. The inner ring 113a improves uniformity of plasma processing with respect to the substrate W. The inner ring 113a is formed of, for example, a conductive material such as silicon (Si) or silicon carbide (SiC). The inner ring 113a may be formed of an insulating material such as quartz. The outer ring 113b has an annular shape. The outer ring 113b is disposed on an outer peripheral portion of the inner ring 113a. The outer ring 113b protects an upper surface of the insulating member 115 from, for example, plasma. The outer ring 113b is formed of, for example, an insulating material such as quartz. The outer ring 113b may be formed of a conductive material such as silicon or silicon carbide. In the illustrated example, an inner peripheral portion of the outer ring 113b is located inside the outer peripheral portion of the inner ring 113a, the outer peripheral portion of the inner ring 113a is located outside the inner peripheral portion of the outer ring 113b, and the inner ring 113a and the outer ring 113b partially overlap with each other. The outer peripheral portion of the inner ring 113a overlaps the inner peripheral portion of the outer ring 113b in a top view. Accordingly, when a plurality of supporting pins 521 to be described later are raised and lowered, the outer ring 113b and the inner ring 113a are raised and lowered as one body. The ring assembly 113 may be a single ring. The insulating member 115 surrounds the lower electrode 111. The insulating member 115 is fixed to a bottom portion of the plasma processing chamber 10 and supports the lower electrode 111.

The upper electrode 12 constitutes the plasma processing chamber 10 together with an insulating member 13. The upper electrode 12 supplies one or more types of processing gases from the gas supply 20 to the plasma processing space 10s. The upper electrode 12 includes a top plate 121 and a support 122. A lower surface of the top plate 121 defines the plasma processing space 10s. A plurality of gas introduction ports 121a are provided in the top plate 121. Each of the gas introduction ports 121a penetrates a plate thickness direction (vertical direction) of the top plate 121. The support 122 detachably supports the top plate 121. A gas diffusion chamber 122a is provided in an interior of the support 122. A plurality of gas introduction ports 122b extend downward from the gas diffusion chamber 122a. The plurality of gas introduction ports 122b communicate with the plurality of gas introduction ports 121a. The support 122 has a gas supply port 122c. The upper electrode 12 supplies one or more processing gases from the gas supply port 122c through the gas diffusion chamber 122a, the plurality of gas introduction ports 122b, and the plurality of gas introduction ports 121a to the plasma processing space 10s.

A sidewall of the plasma processing chamber 10 is provided with a loading and unloading opening 10p. The substrate W is transferred between the plasma processing space 10s and an outside of the plasma processing chamber 10 through the loading and unloading opening 10p. The loading and unloading opening 10p is opened and closed by a gate valve G.

The gas supply 20 includes one or more gas sources 21 and one or more flow rate controllers 22. The gas supply 20 supplies one or more types of processing gases from the gas sources 21 to the gas supply port 122c via the flow rate controllers 22. Each flow rate controller 22 may include, for example, a mass flow controller or a pressure-controlled flow rate controller. The gas supply 20 may include one or more flow rate modulation devices that modulate or pulse the flow rates of one or more processing gases.

The RF power supply 30 includes two RF power supplies (a first RF power supply 31a and a second RF power supply 31b), and two matchers (a first matcher 32a and a second matcher 32b). The first RF power supply 31a supplies first RF power to the lower electrode 111 via the first matcher 32a. A frequency of the first RF power may be, for example, 13 MHz to 150 MHz. The second RF power supply 31b supplies second RF power to the lower electrode 111 via the second matcher 32b. A frequency of the second RF power may be, for example, 400 kHz to 13.56 MHz. Instead of the second RF power supply 31b, a DC power supply may be used.

The exhaust system 40 may be connected to, for example, an exhaust port 10e disposed at the bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The lifter 50 includes a first lifter 51 and a second lifter 52.

The first lifter 51 includes a plurality of supporting pins 511 and an actuator 512. The supporting pins 511 are inserted into a through-holes H1 formed in the lower electrode 111 and the electrostatic chuck 112 and the supporting pins 511 are capable of protruding and retracting from an upper surface of the electrostatic chuck 112. The supporting pins 511 are raised to protrude from the upper surface of the electrostatic chuck 112 to support the substrate W with their upper ends in contact with a lower surface of the substrate W. The actuator 512 raises and lowers the supporting pins 511. As the actuator 512, for example, a motor such as a DC motor, a stepping motor, or a linear motor, an air driving mechanism such as an air cylinder, or a piezoelectric actuator can be used. For example, when transferring the substrate W between the vacuum transfer robot TR1 and the substrate support 11, the first lifter 51 raises and lowers the supporting pins 511.

The second lifter 52 includes the plurality of supporting pins 521 and an actuator 522. The supporting pin 521 is a stepped supporting pin formed of a columnar (solid rod-shaped) member. The supporting pin 521 has a lower pin 523 and an upper pin 524. The upper pin 524 is provided on the lower pin 523. An outer diameter of the lower pin 523 is larger than an outer diameter of the upper pin 524. Accordingly, a stepped portion is formed by an upper end surface 523a of the lower pin 523. The lower pin 523 and the upper pin 524 are integrally molded, for example.

The supporting pin 521 is inserted into a through-hole H11 formed in the lower electrode 111, a through-hole H12 formed in the insulating member 115, and a through-hole H13 formed in the outer ring 113b, and are capable of protruding and retracting from the upper surface of the insulating member 115 and an upper surface of the outer ring 113b. Inner diameters of the through-holes H11 and H12 are slightly larger than the outer diameter of the lower pin 523. An inner diameter of the through-hole H13 is slightly larger than the outer diameter of the upper pin 524 and smaller than the outer diameter of the lower pin 523.

The supporting pin 521 can be displaced between a standby position, a first support position, and a second support position.

The standby position is a position where an upper end surface 524a of the upper pin 524 is lower than a lower surface of the inner ring 113a. When the supporting pin 521 is in the standby position, the inner ring 113a and the outer ring 113b are supported on the electrostatic chuck 112 and the insulating member 115, without being lifted by the supporting pin 521.

The first support position is a position higher than the standby position. The first support position is a position where the upper end surface 524a of the upper pin 524 protrudes above the upper surface of the outer ring 113b, and the upper end surface 523a of the lower pin 523 is below a lower surface of the outer ring 113b. When the supporting pin 521 moves to the first support position, the upper end surface 524a of the upper pin 524 comes into contact with a recess formed in the lower surface of the inner ring 113a to support the inner ring 113a.

The second support position is a position higher than the first support position. The second support position is a position where the upper end surface 523a of the lower pin 523 protrudes above the upper surface of the insulating member 115. When the supporting pin 521 moves to the second support position, the upper end surface 524a of the upper pin 524 comes into contact with the recess to support the inner ring 113a, and the upper end surface 523a of the lower pin 523 comes into contact with the lower surface of the outer ring 113b to support the outer ring 113b.

The actuator 522 raises and lowers the supporting pins 521. The actuator 522 may have a similar configuration as the actuator 512.

When transferring the inner ring 113a between the vacuum transfer robot TR1 and the substrate support 11, the second lifter 52 lifts the inner ring 113a by moving the supporting pins 521 to the first support position. When transferring the inner ring 113a and the outer ring 113b between the vacuum transfer robot TR1 and the substrate support 11, the second lifter 52 lifts the inner ring 113a and the outer ring 113b by moving the supporting pins 521 to the second support position.

The controller 90 controls each part of the plasma processing apparatus 1. The controller 90 includes, for example, a computer 91. The computer 91 includes, for example, a CPU 911, a storage unit 912, and a communication interface 913. The CPU 911 may be configured to perform various control operations based on a program stored in the storage unit 912. The storage unit 912 includes at least one memory type selected from a group consisting of auxiliary storage devices such as a RAM, a ROM, a hard disk drive (HDD), and a solid state drive (SSD). The communication interface 913 may communicate with the plasma processing apparatus 1 through a communication line such as a local area network (LAN). The controller 90 may be provided separately from the controller CU or may be in the controller CU.

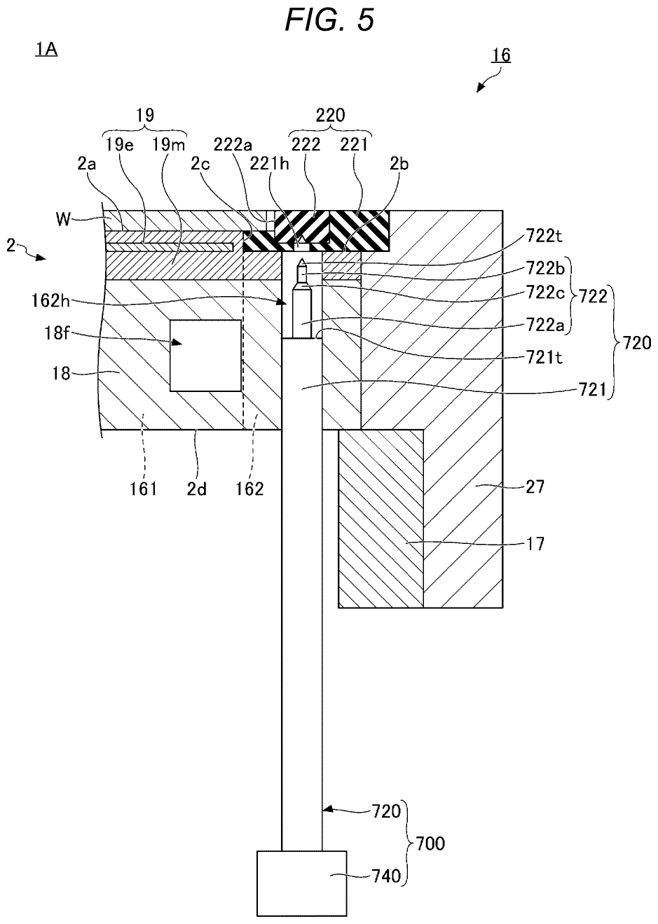

Another example of the plasma processing apparatus that can be applied as the processors PM1 to PM7 illustrated in FIG. 1 will be described with reference to FIG. 5. FIG. 5 is a schematic cross-sectional view illustrating another example of the plasma processing apparatus.

A plasma processing apparatus 1A illustrated in FIG. 5 is different from the plasma processing apparatus 1 in that a substrate support 16 is provided instead of the substrate support 11, and a ring assembly 220 is provided instead of the ring assembly 113. The other configuration may be similar to that of the plasma processing apparatus 1. Hereinafter, the differences from the plasma processing apparatus 1 will be mainly described.

The plasma processing apparatus 1A has the substrate support 16. The substrate support 16 is provided inside the plasma processing chamber 10. The substrate support 16 supports the substrate W. The substrate support 16 is supported by a support 17. The support 17 extends upward from the bottom portion of the plasma processing chamber 10. The support 17 has a substantially cylindrical shape. The support 17 is made of an insulating material such as quartz.

The substrate support 16 has a first portion 161 and a second portion 162. The first portion 161 supports the substrate W. The first portion 161 is substantially circular in a plan view. The first portion 161 may include a base 18 and an electrostatic chuck 19. The first portion 161 may include a part of the base 18 and a part of the electrostatic chuck 19. The base 18 and the electrostatic chuck 19 are provided inside the plasma processing chamber 10. The base 18 is formed of a conductive material such as aluminum. The base 18 has a substantially disk shape. The base 18 configures a lower electrode.

The substrate support 16 includes a main body 2 and the ring assembly 220. The main body 2 includes the base 18 and the electrostatic chuck 19. The main body 2 has a substrate support region 2a for supporting the substrate W, an annular region 2b for supporting the ring assembly 220, and a sidewall 2c extending in the upper-lower direction between the substrate support region 2a and the annular region 2b. The annular region 2b surrounds the substrate support region 2a. The annular region 2b is lower than the substrate support region 2a. Therefore, an upper end of the sidewall 2c is connected to the substrate support region 2a, and a lower end of the sidewall 2c is connected to the annular region 2b.

A flow path 18f is formed inside the base 18. The flow path 18f is a flow path through which a heat exchange medium flows. As the heat exchange medium, a liquid coolant or a coolant (for example, chlorofluorocarbon) for cooling the base 18 by evaporation of the liquid coolant is used. The flow path 18f is connected to a supply device (for example, chiller unit) of the heat exchange medium. The supply device is provided outside the plasma processing chamber 10. The heat exchange medium is supplied from the supply device to the flow path 18f. The heat exchange medium supplied to the flow path 18f is returned to the supply device.

The electrostatic chuck 19 is provided on the base 18. When the substrate W is processed in the plasma processing chamber 10, the substrate W is placed on the first portion 161 and on the electrostatic chuck 19.

The second portion 162 extends radially outside the first portion 161 to surround the first portion 161. The second portion 162 is substantially annular in a plan view. The ring assembly 220 is placed on the second portion 162. The second portion 162 may include the base 18. The second portion 162 may include the electrostatic chuck 19. The second portion 162 may include another part of the base 18 and another part of the electrostatic chuck 19. The substrate W is placed in an area surrounded by the ring assembly 220 and on the electrostatic chuck 19. The ring assembly 220 will be described in detail later.

A through-hole 162h is formed in the second portion 162. The main body 2 has the through-hole 162h formed between the annular region 2b and a lower surface 2d of the main body 2. The through-hole 162h is formed in the second portion 162 to extend along the vertical direction. A plurality of through-holes 162h are formed in the second portion 162. The through-holes 162h may be as many as lift pins 720 in a lift mechanism 700 (described later). Each through-hole 162h is aligned with the corresponding lift pin 720 on a straight line.

The electrostatic chuck 19 has a main body 19m and an electrode 19e. The main body 19m is formed of a dielectric such as aluminum oxide or aluminum nitride. The main body 19m has a substantially disk shape. The electrode 19e is provided in the main body 19m. The electrode 19e has a film shape. The electrode 19e is electrically coupled to a direct-current power supply via a switch. When a voltage from the direct-current power supply is applied to the electrode 19e, an electrostatic attractive force is generated between the electrostatic chuck 19 and the substrate W. The substrate W is attracted to and held by the electrostatic chuck 19 by the generated electrostatic attractive force.

The plasma processing apparatus 1A further includes an outer peripheral member 27. The outer peripheral member 27 extends circumferentially and radially outward from the substrate support 16 to surround the substrate support 16. The outer peripheral member 27 may extend circumferentially and radially outward from the support 17 to surround the support 17. The outer peripheral member 27 may include one or more parts. The outer peripheral member 27 may be formed of an insulating material such as quartz.

The ring assembly 220 and the substrate support 16 will now be described in more detail. The ring assembly 220 includes the lower ring 221 and the upper ring 222.

The lower ring 221 and the upper ring 222 each have an annular shape. The lower ring 221 and the upper ring 222 are each formed of a material appropriately selected according to plasma processing executed in the plasma processing apparatus 1A. The lower ring 221 and the upper ring 222 are each formed of, for example, a conductive material such as silicon or silicon carbide. Each of the lower ring 221 and the upper ring 222 may be formed of an insulating material such as quartz.

The lower ring 221 is disposed on the annular region 2b. The lower ring 221 may be placed on the second portion 162 and on the electrostatic chuck 19. The lower ring 221 may be placed on a component other than the electrostatic chuck 19 in the second portion 162.

The upper ring 222 has a substantially flat lower surface. The lower surface of the upper ring 222 includes a tapered surface and defines a recess. The lower surface of the upper ring 222 defines a plurality of recesses. The tapered surfaces and the recesses on the upper ring 222 may be as many as the lift pins 720 in the lift mechanism 700. Each recess is sized to receive a distal end of a second rod portion 722 of the corresponding lift pin 720. The upper ring 222 is disposed on the lower ring 221 to have the recesses aligned with the corresponding lift pins 720 and corresponding through-holes 221h on a straight line.

The upper ring 222 is accommodated in a recess of the lower ring 221. The lower ring 221 and the upper ring 222 are configured such that when disposed on the annular region 2b, an upper surface of an outer portion of the lower ring 221 and an upper surface of the upper ring 222 are substantially at the same height as an upper surface of the substrate W on the substrate support region 2a. The upper ring 222 has an inner peripheral surface 222a that faces an end surface of the substrate W on the substrate support region 2a when the lower ring 221 and the upper ring 222 are disposed on the annular region 2b.

The ring assembly 220 may be a single ring.

The substrate support 16 includes the lift mechanism 700. The lift mechanism 700 includes the lift pins 720 and is configured to raise and lower the lower ring 221 and the upper ring 222. The lift mechanism 700 includes a plurality of lift pins 720. The number of lift pins 720 may be any number as long as the lift pins 720 are capable of supporting and raising and lowering the ring assembly 220. The lift pins 720 may be three, for example.

Each lift pin 720 may be formed of an insulating material. Each lift pin 720 may be formed of, for example, sapphire, alumina, quartz, silicon nitride, aluminum nitride, or resin. The lift pin 720 includes a first rod portion 721 and the second rod portion 722. The first rod portion 721 extends in the vertical direction. The first rod portion 721 has a first upper end surface 721t. The first upper end surface 721t can come in contact with a lower surface of the lower ring 221.

The second rod portion 722 extends vertically above the first rod portion 721. The second rod portion 722 is narrowed relative to the first rod portion 721 to expose the first upper end surface 721t. Each of the first rod portion 721 and the second rod portion 722 has a columnar shape. A diameter of the first rod portion 721 is larger than a diameter of the second rod portion 722. The second rod portion 722 can move up and down through the through-hole 221h. A length of the second rod portion 722 in the vertical direction is longer than a vertical thickness of a region of the lower ring 221 on which the upper ring 222 is placed.

The second rod portion 722 has a second upper end surface 722t. The second upper end surface 722t can come in contact with the upper ring 222. The distal end of the second rod portion 722 including the second upper end surface 722t may be tapered to be fitted into a corresponding recess in the upper ring 222.

The second rod portion 722 may include a first part 722a and a second part 722b. The first part 722a has a columnar shape and extends upward from the first rod portion 721. The second part 722b has a columnar shape and extends above the first part 722a. The second part 722b includes the second upper end surface 722t. The first part 722a is wider than the second part 722b.

The first rod portion 721, the first part 722a, and the second part 722b may have a columnar shape. The first rod portion 721 has a larger diameter than the first part 722a, and the first part 722a has a larger diameter than the second part 722b.

The second rod portion 722 may include a third part 722c. The third part 722c extends between the first part 722a and the second part 722b. The third part 722c has a tapered surface.

The lift mechanism 700 includes one or more drives 740. The drives 740 are configured to raise and lower the lift pins 720. Each drive 740 may include, for example, a motor.

### Transfer Method

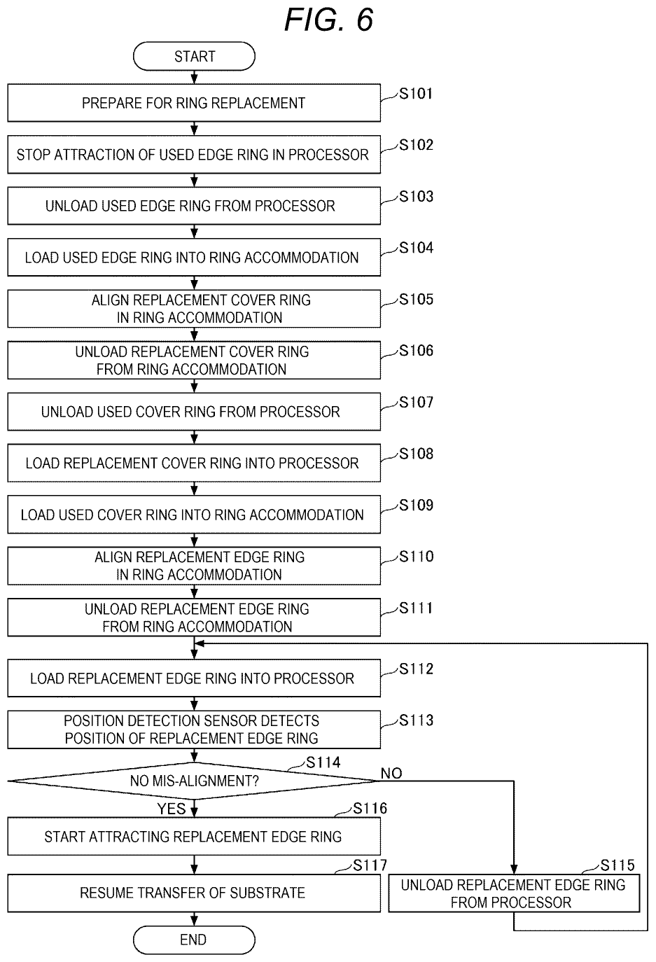

A transfer method according to a first example of the embodiment will be described with reference to FIG. 6. FIG. 6 is a flowchart illustrating the transfer method according to the first example of the embodiment. The transfer method according to the first example of the embodiment is a method of replacing both an edge ring FR and a cover ring CR in the substrate processing system PS described above. The edge ring FR corresponds to the inner ring 113a illustrated in FIG. 4. The cover ring CR corresponds to the outer ring 113b illustrated in FIG. 4. The cover ring CR is an example of a first ring, and the edge ring FR is an example of a second ring.

The transfer method according to the first example of the embodiment starts, for example, when the controller CU receives an instruction to replace both the edge ring FR and the cover ring CR. The instruction to replace both the edge ring FR and the cover ring CR includes, for example, information identifying a processor as a replacement target.

The transfer method according to the first example of the embodiment is performed when, for example, the processor as the replacement target is in a maintenance mode. In the maintenance mode, loading of the substrate into the processor, processing of the substrate in the processor, and unloading of the substrate from the processor are not performed automatically. The transfer method according to the first example of the embodiment may be performed when the processor as the replacement target is in a production mode. In the production mode, loading of the substrate into the processor, processing of the substrate in the processor, and unloading of the substrate from the processor are performed automatically. The transfer method according to the first example of the embodiment may be performed when, for example, a processor that is not the replacement target is in the maintenance mode, or may be performed when a processor that is not the replacement target is in the production mode.

Hereinafter, a case where the processor as the replacement target is the processor PM1 will be described as an example. A case where the processor as the replacement target is the other processors PM2 to PM7 is also similar as the case where the processor as the replacement target is the processor PM1. When the number of processors as the replacement target is two or more, a method when the processor as the replacement target is the processor PM1 is performed for the two or more processors as the replacement target in order.

The transfer method according to the first example of the embodiment includes steps S101 to S117 illustrated in FIG. 6. Steps S101 to S117 are performed as the controller CU controls each part of the substrate processing system PS.

In step S101, upon receiving an instruction to request replacement of the ring assembly, the controller CU executes control to start preparation for replacing the ring assembly.

For example, when the substrate(s) W being processed is present in a processor for performing replacement (i.e., a processor that is scheduled to be replaced) and the other processors, the controller CU waits until the processing is completed, and after the processing, controls the processing system PS to unload the processed substrate(s) W from the processors PM1 to PM7 and transferred into the substrate accommodation container CS1. When the substrate(s) W before and/or after processing is/are present in the vacuum transfer unit TM, the vacuum reserve units LL1 to LL3, and the atmospheric transfer unit LM, the controller CU controls transfer of the substrate(s) W before and/or after processing to the substrate accommodation container CS1. The substrate(s) W that is/are present in the vacuum transfer unit TM and/or the processors PM1 to PM7 is transferred to the vacuum reserve units LL1 to LL3 by the vacuum transfer robot TR1 after or at the same time as transfer of the substrate(s) W that is present in the atmospheric transfer unit LM and the vacuum reserve units LL1 to LL3 to the substrate accommodation container CS1 by the atmospheric transfer robot TR2. Thus, the controller CU controls all the processors PM1 to PM7, the vacuum transfer unit TM, the vacuum reserve units LL1 to LL3, and the atmospheric transfer unit LM so that no substrate W is present therein.

In another example, when the substrate(s) W being processed is present in a processor for performing replacement and the other processors, the controller CU waits until the processing is completed, and after the processing, controls processing system PS to unload the processed substrate(s) W from the processors PM1 to PM7 and transferred into the substrate accommodation container CS1. When the processed substrate(s) W is/are present in the vacuum transfer unit TM, the controller CU controls transfer of the processed substrate W to the substrate accommodation container CS1. When the unprocessed substrate(s) W is/are present in the vacuum transfer unit TM, the controller CU controls transfer of the unprocessed substrate(s) W from the vacuum transfer unit TM to the vacuum reserve units LL1 to LL3. Thus, the controller CU may execute control such that no substrate W is present in at least all the processors PM1 to PM7 and the vacuum transfer unit TM. In this case, ring replacement may be started after all the substrates W are transferred into the substrate accommodation container CS1, or at least after the substrate W is removed from the vacuum transfer unit TM (even if there is the substrate W being transferred from the vacuum reserve units LL1 to LL3 and the atmospheric transfer unit LM to the substrate accommodation container CS1), the ring replacement may be started.

In another example, when processing is being performed in a processor other than the processor for performing the replacement, the controller CU controls the processing to continue, and when the replacement of the ring assembly is not ended after the processing is ended, the substrate W is placed in standby in the processor. When the processed substrate W is present in the vacuum transfer unit TM, the controller CU controls transfer of the processed substrate W to the substrate accommodation container CS1. When the unprocessed substrate W is present in the vacuum transfer unit TM, the controller CU controls transfer of the unprocessed substrate W from the vacuum transfer unit TM to the vacuum reserve units LL1 to LL3. Thus, the controller CU may execute control such that the substrate W is not present at least in the vacuum transfer unit TM. In this case, ring replacement may be started after all the substrates W are transferred into the substrate accommodation container CS1, or at least after the substrate W is removed from the vacuum transfer unit TM (even if there is the substrate W being transferred from the vacuum reserve units LL1 to LL3 and the atmospheric transfer unit LM to the substrate accommodation container CS1), the ring replacement may be started.

In another example, when processing is being performed in a processor other than the processor for performing the replacement, the controller CU controls the processing to continue, and when the replacement of the ring assembly is not ended after the processing is ended, the substrate W is placed in standby in the processor. When the processed substrate W is present in the vacuum transfer unit TM, the controller CU controls transfer of the processed substrate W to the substrate accommodation container CS1. When the unprocessed substrate W is present in the vacuum transfer unit TM, the controller CU controls transfer of the unprocessed substrate W to a processor where the substrate W is to be processed. Thus, the controller CU may execute control such that the substrate W is not present at least in the vacuum transfer unit TM. In this case, ring replacement may be started after all the substrates W are transferred into the substrate accommodation container CS1, or at least after the substrate W is removed from the vacuum transfer unit TM (even if there is the substrate W being transferred from the vacuum reserve units LL1 to LL3 and the atmospheric transfer unit LM to the substrate accommodation container CS1), the ring replacement may be started.

A request for replacing the ring assembly may be instructed by an operator via a GUI (input screen), or the substrate processing system PS may be configured to automatically start replacing processing when a replacement timing comes.

Step S101 may include the controller CU determining whether the substrate W is located in the atmospheric transfer unit LM, the aligner AN, the vacuum reserve units LL1 to LL3, the vacuum transfer unit TM, and the processors PM1 to PM7. For example, the controller CU determines whether the substrate W is located in the atmospheric transfer unit LM, the aligner AN, the vacuum reserve units LL1 to LL3, the vacuum transfer unit TM, and the processors PM1 to PM7, based on a transfer history of the substrate W by the vacuum transfer robot TR1. When the controller CU determines that there is no substrate W in the atmospheric transfer unit LM, the aligner AN, the vacuum reserve units LL1 to LL3, the vacuum transfer unit TM, and the processors PM1 to PM7, the controller CU controls the process to proceed to step S102. At least when the controller CU determines that there is no substrate W in the vacuum transfer unit TM and the processors PM1 to PM7, the process may be controlled to proceed to step S102.

In step S102, the controller CU stops attraction of the used edge ring FR attracted and held by the electrostatic chuck 112.

In step S103, the vacuum transfer robot TR1 unloads the used edge ring FR from the processor PM1 by the lower fork FK2. In step S103, the vacuum transfer robot TR1 may unload the used edge ring FR from the processor PM1 by the upper fork FK1.

In step S104, the vacuum transfer robot TR1 loads the used edge ring FR unloaded from the processor PM1 in step S103 into the ring accommodation RSM.

In step S105, an aligner (not shown) provided in the ring accommodation RSM performs alignment of the replacement cover ring CR accommodated in the ring accommodation RSM. The replacement cover ring CR may be new (unused) or may be used but not very worn. The alignment may include aligning a rotational position of the replacement cover ring CR to a target position. The alignment may include aligning a center position of the replacement cover ring CR to a target position.

In step S106, the vacuum transfer robot TR1 unloads the replacement cover ring CR aligned in step S105 from the ring accommodation RSM by the upper fork FK1.

In step S107, the vacuum transfer robot TR1 unloads the used cover ring CR from the processor PM1 by the lower fork FK2 while the replacement cover ring CR unloaded from the ring accommodation RSM in step S106 is held by the upper fork FK1. The used cover ring CR may be, for example, a used cover ring that is used during processing of the substrate W in the processor PM1.

In step S108, the vacuum transfer robot TR1 loads the replacement cover ring CR held by the upper fork FK1 into the processor PM1. Thus, when the vacuum transfer robot TR1 holds the replacement cover ring CR with the upper fork FK1 and holds the used cover ring CR with the lower fork FK2, the replacement cover ring CR is located above the used cover ring CR. Therefore, even when particles or the like that adhere to the used cover ring CR fall, it is possible to prevent the particles or the like from adhering to the replacement cover ring CR. In step S106, the vacuum transfer robot TR1 may unload the replacement cover ring CR from the ring accommodation RSM by the lower fork FK2, and in step S107, the vacuum transfer robot TR1 may unload the used cover ring CR from the processor PM1 by the upper fork FK1.

In step S109, the vacuum transfer robot TR1 loads the used cover ring CR unloaded from the processor PM1 in step S107 into the ring accommodation RSM.

In step S110, an aligner (not shown) provided in the ring accommodation RSM performs alignment of the replacement edge ring FR accommodated in the ring accommodation RSM. The replacement edge ring FR may be new (unused) or may be used but not very worn. The alignment may include aligning a rotational position of the replacement edge ring FR to a target position. The alignment may include aligning a center position of the replacement edge ring FR to a target position.

In step S111, the vacuum transfer robot TR1 unloads the replacement edge ring FR aligned in step S110 from the ring accommodation RSM by the upper fork FK1. In step S111, the vacuum transfer robot TR1 may unload the replacement edge ring FR from the ring accommodation RSM by the lower fork FK2.

In step S112, the vacuum transfer robot TR1 loads the replacement edge ring FR unloaded from the ring accommodation RSM in step S111 into the processor PM1.

In step S113, the position detection sensor S1 provided in the upper fork FK1 detects a position of the replacement edge ring FR loaded into the processor PM1.

In step S114, the controller CU determines whether there is any mis-alignment in the replacement edge ring FR, based on the position of the replacement edge ring FR detected in step S113. If it is determined that there is mis-alignment in the replacement edge ring FR (NO in step S114), the controller CU advances the process to step S115. If it is determined that there is no mis-alignment in the replacement edge ring FR (YES in step S114), the controller CU advances the process to step S116.

In step S115, the vacuum transfer robot TR1 unloads the replacement edge ring FR from the processor PM1 by the upper fork FK1. In step S115, the vacuum transfer robot TR1 may unload the replacement edge ring FR from the processor PM1 by the lower fork FK2. After step S115, the process returns to step S112, and the vacuum transfer robot TR1 corrects a position of the replacement edge ring FR unloaded from the processor PM1 in step S115, and loads the replacement edge ring FR into the processor PM1. In step S115, the position of the replacement edge ring FR may be corrected without being unloaded from the processor PM1. In this case, first, the supporting pins 511 provided in the processor PM1 are raised to lift the replacement edge ring FR. Subsequently, the vacuum transfer robot TR1 causes the upper fork FK1 (or the lower fork FK2) to enter the processor PM1. Subsequently, the supporting pins 511 are lowered to deliver the replacement edge ring FR to the upper fork FK1 (or the lower fork FK2). Subsequently, the vacuum transfer robot TR1 corrects the position of the replacement edge ring FR by adjusting a position of the upper fork FK1 (or the lower fork FK2) in the processing chamber of the processor PM1.

In step S116, the controller CU starts attracting and holding the replacement edge ring FR by the electrostatic chuck 112.

In step S117, the controller CU resumes transfer of the substrate W by the vacuum transfer robot TR1.

According to the transfer method of the first example of the embodiment described above, the vacuum transfer robot TR1 transfers the edge ring FR and the cover ring CR between the processor PM1 and the ring accommodation RSM with at least all the substrates are removed from the vacuum transfer unit TM. Accordingly, the transfer of the substrate W by the vacuum transfer robot TR1 and the transfer of the edge ring FR and the cover ring CR by the vacuum transfer robot TR1 do not coexist. Therefore, it is possible to prevent adhesion of particles or the like to the substrate W that may occur during the transfer of the edge ring FR and the cover ring CR. As a result, it is possible to prevent contamination of the substrate W.

An order of a part of step S101 to step S117 illustrated in FIG. 6 may be changed.

For example, step S101 and step S102 may be performed in parallel.

For example, step S105 may be performed between step S101 and step S102, may be performed between step S102 and step S103, or may be performed between step S103 and step S104. For example, step S105 may be performed in parallel with at least one of step S102, step S103, and step S104.

For example, step S110 may be performed between step S105 and step S106. For example, step S110 may be performed between step S106 and step S107. For example, step S110 may be performed between step S107 and step S108. For example, step S110 may be performed between step S108 and step S109. For example, step S110 may be performed in parallel with at least one of step S106, step S107, step S108, and step S109.

A part of steps S101 to S117 illustrated in FIG. 6 may not be performed. For example, when the edge ring FR is not attracted and held by the electrostatic chuck 112, step S102 and step S116 may be omitted.

Another step may be added to steps S101 to S117 illustrated in FIG. 6. For example, after the vacuum transfer robot TR1 loads the replacement cover ring CR into the processor PM1 in step S108, a position of the replacement cover ring CR may be corrected when the replacement cover ring CR is misaligned, as in steps S113, S114, and S115.

After steps S101 to S117 illustrated in FIG. 6 are ended, the method may include supplying a heat transfer gas to a rear surface of the edge ring FR from a gas supply line (not shown). For example, the method may include supplying a heat transfer gas to the rear surface of the edge ring FR during execution of substrate processing. The heat transfer gas may be, for example, helium (He) gas.

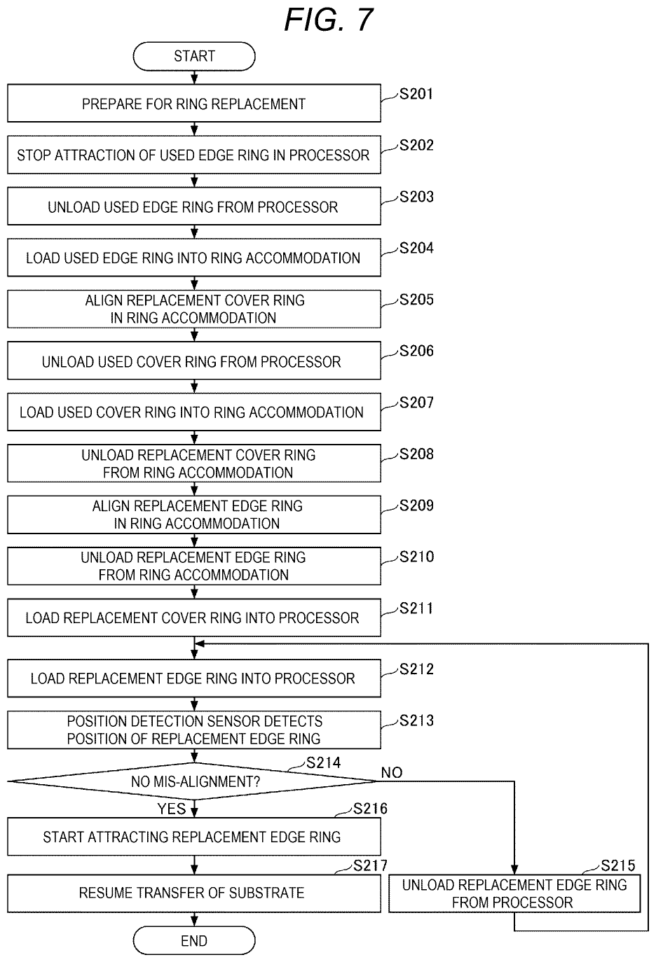

A transfer method according to a second example of the embodiment will be described with reference to FIG. 7. FIG. 7 is a flowchart illustrating a transfer method according to the second example of the embodiment. The transfer method according to the second example of the embodiment is a method of replacing both the edge ring FR and the cover ring CR in the substrate processing system PS described above.

The transfer method according to the second example of the embodiment starts, for example, when the controller CU receives an instruction to replace both the edge ring FR and the cover ring CR. The instruction to replace both the edge ring FR and the cover ring CR includes, for example, information identifying a processor as a replacement target.

Similar to the transfer method according to the first example of the embodiment, for example, a transfer method according to the second example of the embodiment is performed regardless of a state of the processor that is the replacement target and a state of the processor that is not the replacement target.

Hereinafter, a case where the processor as the replacement target is the processor PM1 will be described as an example. A case where the processor as the replacement target is the other processors PM2 to PM7 is also similar as the case where the processor as the replacement target is the processor PM1. When the number of processors as the replacement target is two or more, a method when the processor as the replacement target is the processor PM1 is performed for the two or more processors as the replacement target in order.

The transfer method according to the second example of the embodiment includes steps S201 to S217 illustrated in FIG. 7. Steps S201 to S217 are performed as the controller CU controls each part of the substrate processing system PS.

Steps S201 to S205 may be similar to steps S101 to S105.

In step S206, the vacuum transfer robot TR1 unloads the used cover ring CR from the processor PM1 by the lower fork FK2. In step S206, the vacuum transfer robot TR1 may unload the used cover ring CR from the processor PM1 by the upper fork FK1.

In step S207, the vacuum transfer robot TR1 loads the used cover ring CR unloaded from the processor PM1 in step S206 into the ring accommodation RSM.

In step S208, the vacuum transfer robot TR1 unloads the replacement cover ring CR aligned in step S205 from the ring accommodation RSM by the upper fork FK1. In step S208, the vacuum transfer robot TR1 may unload the replacement cover ring CR aligned in step S205 from the ring accommodation RSM by the lower fork FK2.

In step S209, an aligner (not shown) provided in the ring accommodation RSM performs alignment of the replacement edge ring FR accommodated in the ring accommodation RSM.

In step S210, the vacuum transfer robot TR1 unloads the replacement edge ring FR aligned in step S209 from the ring accommodation RSM by a fork that does not hold the replacement cover ring CR, for example, the lower fork FK2.

In step S211, the vacuum transfer robot TR1 loads the replacement cover ring CR held by the upper fork FK1 into the processor PM1.

Steps S212 to S217 may be similar to steps S112 to S117.

According to the transfer method of the second example of the embodiment described above, the vacuum transfer robot TR1 transfers the edge ring FR and the cover ring CR between the processor PM1 and the ring accommodation RSM with at least all the substrates are removed from the vacuum transfer unit TM. Accordingly, the transfer of the substrate W by the vacuum transfer robot TR1 and the transfer of the edge ring FR and the cover ring CR by the vacuum transfer robot TR1 do not coexist. Therefore, it is possible to prevent adhesion of particles or the like to the substrate W that may occur during the transfer of the edge ring FR and the cover ring CR. As a result, it is possible to prevent contamination of the substrate W.

According to the transfer method of the second example of the embodiment, the vacuum transfer robot TR1 does not hold the used ring (the used edge ring FR and the used cover ring CR) and the replacement ring (the replacement edge ring FR and the replacement cover ring CR) at the same time. Therefore, it is easy to prevent particles or the like that may occur during the transfer of the used ring from adhering to the replacement ring.

An order of a part of step S201 to step S217 illustrated in FIG. 7 may be changed.

For example, step S201 and step S202 may be performed in parallel.

For example, step S205 may be performed between step S201 and step S202, may be performed between step S202 and step S203, or may be performed between step S203 and step S204. For example, step S205 may be performed in parallel with at least one of step S202, step S203, and step S204.

A part of steps S201 to S217 illustrated in FIG. 7 may not be performed. For example, when the edge ring FR is not attracted and held by the electrostatic chuck 112, step S202 and step S216 may be omitted.

Another step may be added to steps S201 to S217 illustrated in FIG. 7. For example, after the vacuum transfer robot TR1 loads the replacement cover ring CR into the processor PM1 in step S211, a position of the replacement cover ring CR may be corrected when the replacement cover ring CR is misaligned, as in steps S213, S214, and S215.

After steps S201 to S217 illustrated in FIG. 7 are ended, the method may include supplying a heat transfer gas to a rear surface of the edge ring FR from a gas supply line (not shown). For example, the method may include supplying a heat transfer gas to the rear surface of the edge ring FR during execution of substrate processing.

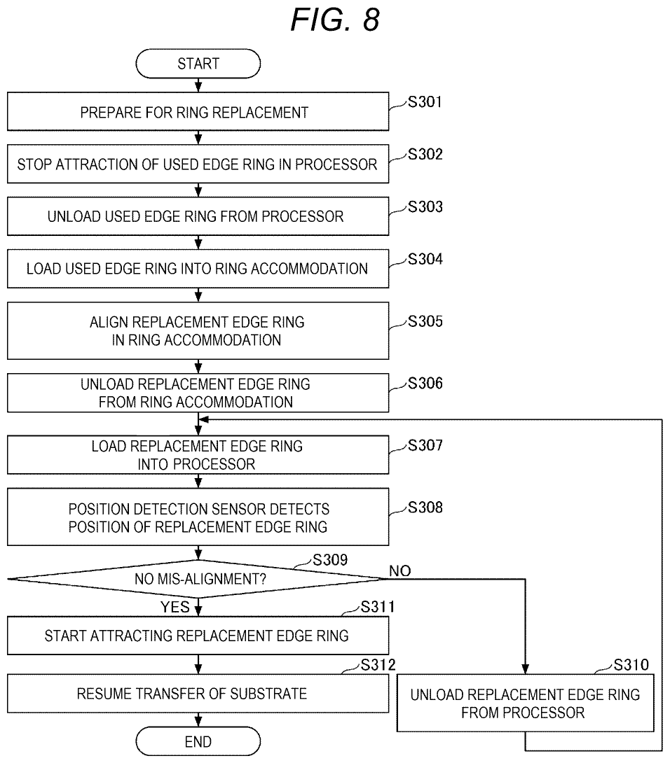

A transfer method according to a third example of the embodiment will be described with reference to FIG. 8. FIG. 8 is a flowchart illustrating the transfer method according to the third example of the embodiment. The transfer method according to the third example of the embodiment is a method of replacing only the edge ring FR without replacing the cover ring CR in the substrate processing system PS described above.

The transfer method according to the third example of the embodiment starts when the controller CU receives an instruction to replace the edge ring FR alone. The instruction to replace the edge ring FR alone includes, for example, information identifying a processor as a replacement target.

Similar to the transfer method according to the first example of the embodiment, for example, the transfer method according to the third example of the embodiment is performed regardless of a state of the processor that is the replacement target and a state of the processor that is not the replacement target.

Hereinafter, a case where the processor as the replacement target is the processor PM1 will be described as an example. A case where the processor as the replacement target is the other processors PM2 to PM7 is also similar as the case where the processor as the replacement target is the processor PM1. When the number of processors as the replacement target is two or more, a method when the processor as the replacement target is the processor PM1 is performed for the two or more processors as the replacement target in order.

The transfer method according to the third example of the embodiment includes steps S301 to S312 illustrated in FIG. 8. Steps S301 to S312 are performed as the controller CU controls each part of the substrate processing system PS. Steps S301 to S304 may be similar to steps S101 to S104. Steps S305 to S312 may be similar to steps S110 to S117.

According to the transfer method of the third example of the embodiment described above, the vacuum transfer robot TR1 transfers the edge ring FR between the processor PM1 and the ring accommodation RSM with at least all the substrates are removed from the vacuum transfer unit TM. Accordingly, the transfer of the substrate W by the vacuum transfer robot TR1 and the transfer of the edge ring FR by the vacuum transfer robot TR1 do not coexist. Therefore, it is possible to prevent adhesion of particles or the like to the substrate W that may occur during the transfer of the edge ring FR. As a result, it is possible to prevent contamination of the substrate W.

An order of a part of step S301 to step S312 illustrated in FIG. 8 may be changed.

For example, step S301 and step S302 may be performed in parallel.

For example, step S305 may be performed between step S301 and step S302, may be performed between step S302 and step S303, or may be performed between step S303 and step S304. For example, step S305 may be performed in parallel with at least one of step S302, step S303, and step S304.

A part of steps S301 to S312 illustrated in FIG. 8 may not be performed. For example, when the edge ring FR is not attracted and held by the electrostatic chuck 112, step S302 and step S311 may be omitted.

After steps S301 to S312 illustrated in FIG. 8 are ended, the method may include supplying a heat transfer gas to a rear surface of the edge ring FR from a gas supply line (not shown). For example, the method may include supplying a heat transfer gas to the rear surface of the edge ring FR during execution of substrate processing.

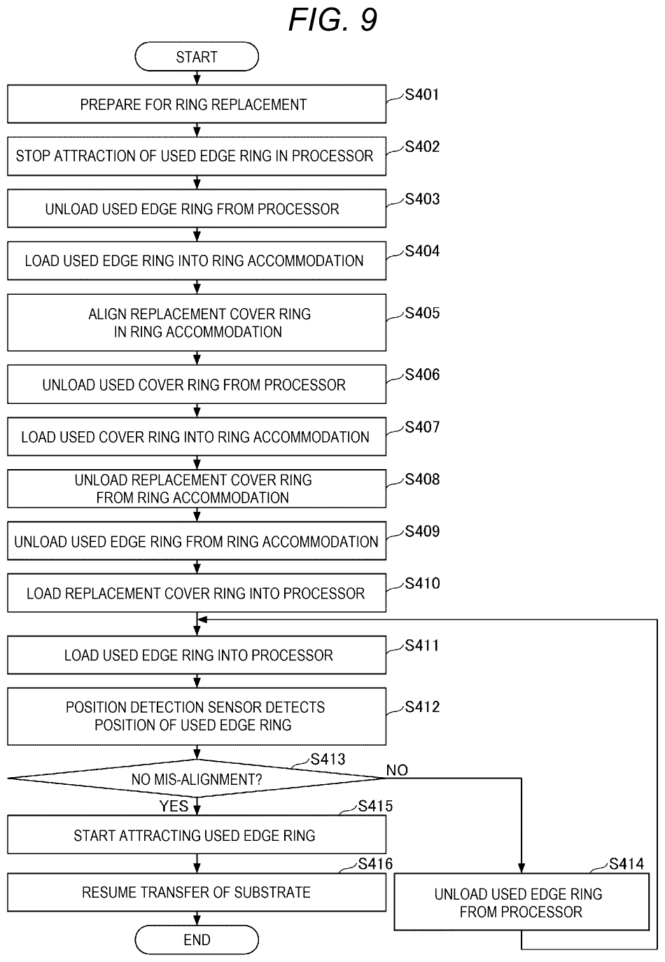

A transfer method according to a fourth example of the embodiment will be described with reference to FIG. 9. FIG. 9 is a flowchart illustrating the transfer method according to the fourth example of the embodiment. The transfer method according to the fourth example of the embodiment is a method of replacing only the cover ring CR without replacing the edge ring FR in the substrate processing system PS described above.

The transfer method according to the fourth example of the embodiment starts when the controller CU receives an instruction to replace the cover ring CR alone. The instruction to replace the cover ring CR alone includes, for example, information identifying a processor as a replacement target.

Similar to the transfer method according to the first example of the embodiment, for example, the transfer method according to the fourth example of the embodiment is performed regardless of a state of the processor that is the replacement target and a state of the processor that is not the replacement target.

Hereinafter, a case where the processor as the replacement target is the processor PM1 will be described as an example. A case where the processor as the replacement target is the other processors PM2 to PM7 is also similar as the case where the processor as the replacement target is the processor PM1. When the number of processors as the replacement target is two or more, a method when the processor as the replacement target is the processor PM1 is performed for the two or more processors as the replacement target in order.

The transfer method according to the fourth example of the embodiment includes steps S401 to S416 illustrated in FIG. 9. Steps S401 to S416 are performed as the controller CU controls each part of the substrate processing system PS.

Steps S401 to S408 may be similar to steps S201 to S208.

In step S409, the vacuum transfer robot TR1 unloads the used edge ring FR accommodated in the ring accommodation RSM in step S404 from the ring accommodation RSM by a fork that does not hold the replacement cover ring CR, for example, the lower fork FK2. Thus, when the vacuum transfer robot TR1 holds the replacement cover ring CR with the upper fork FK1 and holds the used edge ring FR with the lower fork FK2, the replacement cover ring CR is located above the used edge ring FR. Therefore, even when particles or the like that adhere to the used edge ring FR fall, it is possible to prevent the particles or the like from adhering to the replacement cover ring CR. In step S408, the vacuum transfer robot TR1 may unload the replacement cover ring CR from the ring accommodation RSM by the lower fork FK2, and in step S409, the vacuum transfer robot TR1 may unload the used edge ring FR from the processor PM1 by the upper fork FK1.

In step S410, the vacuum transfer robot TR1 loads the replacement cover ring CR unloaded from the ring accommodation RSM in step S408 into the processor PM1.

In step S411, the vacuum transfer robot TR1 loads the used edge ring FR unloaded from the ring accommodation RSM in step S409 into the processor PM1.

In step S412, the position detection sensor S2 provided in the lower fork FK2 detects a position of the used edge ring FR loaded into the processor PM1.

In step S413, the controller CU determines whether there is any mis-alignment in the used edge ring FR, based on the position of the used edge ring FR detected in step S412. If it is determined that there is mis-alignment in the used edge ring FR (NO in step S413), the controller CU advances the process to step S414. If it is determined that there is no mis-alignment in the used edge ring FR (YES in step S413), the controller CU advances the process to step S415.

In step S414, the vacuum transfer robot TR1 unloads the used edge ring FR from the processor PM1 by the upper fork FK1. In step S414, the vacuum transfer robot TR1 may unload the used edge ring FR from the processor PM1 by the lower fork FK2. After step S414, the process returns to step S411, and the vacuum transfer robot TR1 corrects a position of the used edge ring FR unloaded from the processor PM1 in step S414, and loads the used edge ring FR into the processor PM1. Alternatively, in step S414, the position of the used edge ring FR may be corrected without being unloaded from the processor PM1. In this case, first, the supporting pins 511 provided in the processor PM1 are raised to lift the used edge ring FR. Subsequently, the vacuum transfer robot TR1 causes the upper fork FK1 (or the lower fork FK2) to enter the processor PM1. Subsequently, the supporting pins 511 are lowered to deliver the used edge ring FR to the upper fork FK1 (or the lower fork FK2). Subsequently, the vacuum transfer robot TR1 corrects the position of the used edge ring FR by adjusting a position of the upper fork FK1 (or the lower fork FK2) in the processing chamber of the processor PM1.

In step S415, the controller CU starts attracting and holding the used edge ring FR by the electrostatic chuck 112.

In step S416, the controller CU resumes transfer of the substrate W by the vacuum transfer robot TR1.

According to the transfer method of the fourth example of the embodiment described above, the vacuum transfer robot TR1 transfers the edge ring FR and the cover ring CR between the processor PM1 and the ring accommodation RSM with at least all the substrates are removed from the vacuum transfer unit TM. Accordingly, the transfer of the substrate W by the vacuum transfer robot TR1 and the transfer of the edge ring FR and the cover ring CR by the vacuum transfer robot TR1 do not coexist. Therefore, it is possible to prevent adhesion of particles or the like to the substrate W that may occur during the transfer of the edge ring FR and the cover ring CR. As a result, it is possible to prevent contamination of the substrate W.

An order of a part of step S401 to step S416 illustrated in FIG. 9 may be changed.

For example, step S401 and step S402 may be performed in parallel.

For example, step S405 may be performed between step S401 and step S402, may be performed between step S402 and step S403, or may be performed between step S403 and step S404. For example, step S405 may be performed in parallel with at least one of step S402, step S403, and step S404.

A part of steps S401 to S416 illustrated in FIG. 9 may not be performed. For example, when the edge ring FR is not attracted and held by the electrostatic chuck 112, step S402 and step S415 may be omitted.

Another step may be added to steps S401 to S416 illustrated in FIG. 9. For example, after the vacuum transfer robot TR1 loads the replacement cover ring CR into the processor PM1 in step S410, a position of the replacement cover ring CR may be corrected when the replacement cover ring CR is misaligned, as in steps S412, S413, and S414.

After steps S401 to S416 illustrated in FIG. 9 are ended, the method may include supplying a heat transfer gas to a rear surface of the edge ring FR from a gas supply line (not shown). For example, the method may include supplying a heat transfer gas to the rear surface of the edge ring FR during execution of substrate processing.

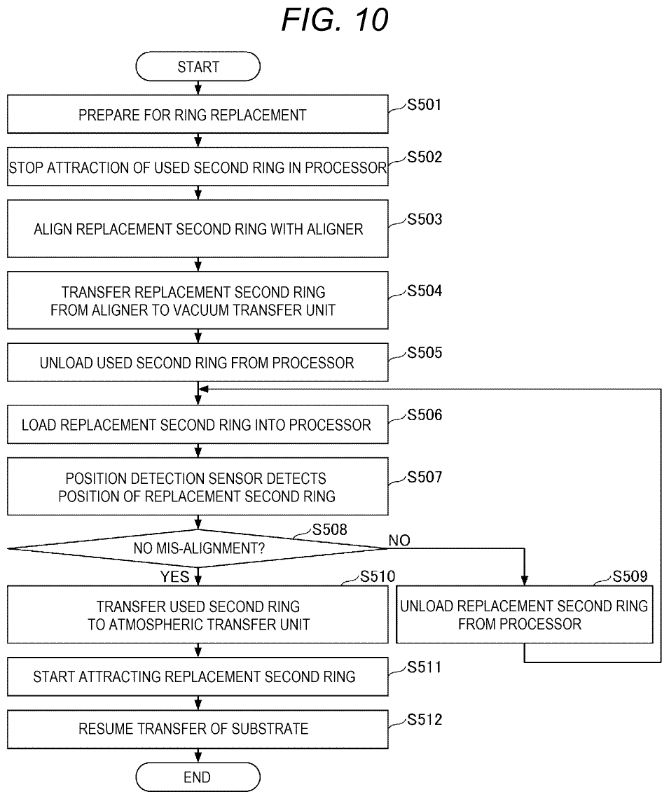

A transfer method according to a fifth example of the embodiment will be described with reference to FIG. 10. FIG. 10 is a flowchart illustrating the transfer method according to the fifth example of the embodiment. The transfer method according to the fifth example of the embodiment is a method of replacing a second ring PFR in the substrate processing system PS described above.

The second ring PFR corresponds to the upper ring 222 illustrated in FIG. 5. Therefore, the second ring PFR is stored in, for example, the ring accommodation container CS2 placed in the load port LP4. The lower ring 221 illustrated in FIG. 5 can also be replaced in the same manner as the upper ring 222.

The transfer method according to the fifth example of the embodiment starts when the controller CU receives an instruction to replace the second ring PFR alone. The instruction to replace the second ring PFR alone includes, for example, information identifying a processor as a replacement target.

Similar to the transfer method according to the first example of the embodiment, for example, the transfer method according to the fifth example of the embodiment is performed regardless of a state of the processor that is the replacement target and a state of the processor that is not the replacement target.

Hereinafter, a case where the processor as the replacement target is the processor PM1 will be described as an example. A case where the processor as the replacement target is the other processors PM2 to PM7 is also similar as the case where the processor as the replacement target is the processor PM1. When the number of processors as the replacement target is two or more, a method when the processor as the replacement target is the processor PM1 is performed for the two or more processors as the replacement target in order.

The transfer method according to the fifth example of the embodiment includes steps S501 to S512 illustrated in FIG. 10. Steps S501 to S512 are performed as the controller CU controls each part of the substrate processing system PS.

Step S501 may be similar to step S101.

In step S502, the controller CU stops attraction of the used second ring PFR attracted and held by the electrostatic chuck 112. The used second ring PFR may be, for example, a used second ring that is used during processing of the substrate W in the processor PM1.

In step S503, the atmospheric transfer robot TR2 loads the replacement second ring PFR accommodated in the ring accommodation container CS2 placed in the load port LP4 into the aligner AN, and the aligner AN aligns the replacement second ring PFR. The replacement second ring PFR may be new (unused) or may be used but not very worn. The alignment may include aligning a rotational position of the replacement second ring PFR to a target position. The alignment may include aligning a center position of the replacement second ring PFR to a target position.

In step S504, the replacement second ring PFR aligned in step S503 is transferred from the aligner AN to the vacuum transfer unit TM. Specifically, first, the atmospheric transfer robot TR2 unloads the replacement second ring PFR aligned in step S503 from the aligner AN, and loads the second ring PFR into the vacuum reserve unit LL3, the inside of which is pressurized to the atmospheric pressure. Next, the inside of the vacuum reserve unit LL3 is depressurized. Next, the vacuum transfer robot TR1 unloads the replacement second ring PFR from the vacuum reserve unit LL3 by the upper fork FK1. In step S504, the vacuum reserve units LL1 and LL2 may be used instead of the vacuum reserve unit LL3.

In step S505, the vacuum transfer robot TR1 unloads the used second ring PFR from the processor PM1 by the lower fork FK2.

In step S506, the vacuum transfer robot TR1 loads the replacement second ring PFR held by the upper fork FK1 into the processor PM1. Thus, when the vacuum transfer robot TR1 holds the replacement second ring PFR with the upper fork FK1 and holds the used second ring PFR with the lower fork FK2, the replacement second ring PFR is located above the used second ring PFR. Therefore, even when particles or the like that adhere to the used second ring PFR fall, it is possible to prevent the particles or the like from adhering to the replacement second ring PFR. In step S504, the vacuum transfer robot TR1 may unload the replacement second ring PFR from the vacuum reserve unit LL3 by the lower fork FK2. In step S505, the vacuum transfer robot TR1 may unload the used second ring PFR from the processor PM1 by the upper fork FK1.

In step S507, the position detection sensor S1 provided in the upper fork FK1 detects a position of the replacement second ring PFR loaded into the processor PM1.

In step S508, the controller CU determines whether there is any mis-alignment in the replacement second ring PFR, based on the position of the replacement second ring PFR detected in step S507. If it is determined that there is mis-alignment in the replacement second ring PFR (NO in step S508), the controller CU advances the process to step S509. If it is determined that there is no mis-alignment in the replacement second ring PFR (YES in step S508), the controller CU advances the process to step S510.

In step S509, the vacuum transfer robot TR1 unloads the replacement second ring PFR from the processor PM1 by the upper fork FK1. In step S509, the vacuum transfer robot TR1 may unload the replacement second ring PFR from the processor PM1 by the lower fork FK2. After step S509, the process returns to step S506, and in step S506, the vacuum transfer robot TR1 corrects a position of the replacement second ring PFR unloaded from the processor PM1 in step S509, and loads the replacement second ring PFR into the processor PM1. Alternatively, in step S509, the position of the replacement second ring PFR may be corrected without being unloaded from the processor PM1. In this case, first, the supporting pins 511 provided in the processor PM1 are raised to lift the replacement second ring PFR. Subsequently, the vacuum transfer robot TR1 causes the upper fork FK1 (or the lower fork FK2) to enter the processor PM1. Subsequently, the supporting pins 511 are lowered to deliver the replacement second ring PFR to the upper fork FK1 (or the lower fork FK2). Subsequently, the vacuum transfer robot TR1 corrects the position of the replacement second ring PFR by adjusting a position of the upper fork FK1 (or the lower fork FK2) in the processing chamber of the processor PM1.

In step S510, the used second ring PFR unloaded from the processor PM1 in step S505 is transferred from the vacuum transfer unit TM to the atmospheric transfer unit LM. Specifically, first, the vacuum transfer robot TR1 loads the used second ring PFR held by the lower fork FK2 into the vacuum reserve unit LL1, the inside of which is depressurized to vacuum. Next, the vacuum reserve unit LL1 pressurizes the inside to the atmospheric pressure. Next, the atmospheric transfer robot TR2 unloads the used second ring PFR from the vacuum reserve unit LL1, and loads the unloaded used second ring PFR into the ring accommodation container CS2 placed in the load port LP4. In step S510, the vacuum reserve units LL2 and LL3 may be used instead of the vacuum reserve unit LL1.

In step S511, the controller CU starts attracting and holding the replacement second ring PFR by the electrostatic chuck 112.

In step S512, the controller CU resumes transfer of the substrate W by the vacuum transfer robot TR1.

According to the transfer method of the fifth example of the embodiment described above, the vacuum transfer robot TR1 transfers the second ring PFR between the processor PM1 and the atmospheric transfer unit LM with at least all the substrates are removed from the vacuum transfer unit TM. Accordingly, the transfer of the substrate W by the vacuum transfer robot TR1 and the transfer of the second ring PFR by the vacuum transfer robot TR1 do not coexist. Therefore, it is possible to prevent adhesion of particles or the like to the substrate W that may occur during the transfer of the second ring PFR. As a result, it is possible to prevent contamination of the substrate W.

An order of a part of step S501 to step S512 illustrated in FIG. 10 may be changed.

For example, step S501 and step S502 may be performed in parallel.

For example, step S503 may be performed between step S501 and step S502. For example, step S503 may be performed in parallel with step S502.

A part of steps S501 to S512 illustrated in FIG. 10 may not be performed. For example, when the second ring PFR is not attracted and held by the electrostatic chuck 112, step S502 and step S511 may be omitted.

The embodiments disclosed above include, for example, the following aspects.

### (Appendix 1)

A substrate processing system including:
a plurality of processors each including a substrate support supporting a substrate and a ring disposed around the substrate,
a vacuum transfer unit connected to the processors, the vacuum transfer unit including a transfer robot configured to transfer the substrate or the ring,
an accommodation configured to accommodate the ring, and
a controller configured to execute control to remove all the substrates from the processors and the vacuum transfer unit, and after the removing, configured to execute control to transfer the ring between at least one of the processors and the accommodation.

### (Appendix 2)

The substrate processing system according to appendix 1, further including:
a vacuum reserve unit connected to the vacuum transfer unit, and
an atmospheric transfer unit connected to the vacuum transfer unit via the vacuum reserve unit, in which
the controller executes control to, in the removing, remove all the substrates from the vacuum reserve unit and the atmospheric transfer unit.

### (Appendix 3)

The substrate processing system according to appendix 1, in which
the controller executes control to, after the removing and before the transferring, load all the removed substrates into a substrate accommodation container.

### (Appendix 4)

The substrate processing system according to appendix 2, in which
the controller executes control to, after the removing and before the transferring, load all the removed substrates into a substrate accommodation container.

### (Appendix 5)

The substrate processing system according to any one of appendixes 1 to 4, in which
the accommodation includes a ring accommodation connected to the vacuum transfer unit.

### (Appendix 6)

The substrate processing system according to appendix 5, in which
the ring includes a first ring and a second ring disposed on the first ring, and
the controller executes control to, in the transferring, replace both the first ring and the second ring.

### (Appendix 7)

The substrate processing system according to appendix 6, in which
the controller executes control to, in the transferring,
   unload a used second ring from the processor,
   after unloading the second ring, unload a used first ring from the processor,
   after unloading the first ring, load a replacement first ring into the processor, and
   after loading the first ring, load a replacement second ring into the processor.

### (Appendix 8)

The substrate processing system according to appendix 7, in which
the controller executes control to, in the transferring,
   load the used second ring unloaded from the processor into the ring accommodation, and
   load the used first ring unloaded from the processor into the ring accommodation.

### (Appendix 9)

The substrate processing system according to appendix 7, in which
the accommodation includes an aligner, and
the controller executes control to, in the transferring, before loading the replacement first ring accommodated in the accommodation, load the first ring into the aligner.

### (Appendix 10)

The substrate processing system according to appendix 8, in which
the accommodation includes an aligner, and
the controller executes control to, in the transferring, before loading the first ring, load the replacement first ring accommodated in the accommodation into the aligner.

### (Appendix 11)

The substrate processing system according to appendix 7, in which
the accommodation includes an aligner, and
the controller executes control to, in the transferring, before loading the replacement second ring accommodated in the accommodation, load the second ring into the aligner.

### (Appendix 12)

The substrate processing system according to appendix 8, in which
the accommodation includes an aligner, and
the controller executes control to, in the transferring, before loading the second ring, load the replacement second ring accommodated in the accommodation into the aligner.

### (Appendix 13)

The substrate processing system according to appendix 2, further including:
a load port connected to the atmospheric transfer unit, in which
the accommodation includes a ring accommodation placed in the load port.

### (Appendix 14)

The substrate processing system according to appendix 13, in which
the ring includes a first ring and a second ring disposed on the first ring, and
the controller executes control to, in the transferring, replace the second ring without replacing the first ring.

### (Appendix 15)

The substrate processing system according to appendix 14, in which
the controller executes control to, in the transferring,
   unload a used second ring from the processor, and
   load a replacement second ring into the processor.

### (Appendix 16)

The substrate processing system according to appendix 15, in which
the controller executes control to, in the transferring, load the used second ring unloaded from the processor into the ring accommodation.

### (Appendix 17)

The substrate processing system according to appendix 15 or 16, in which
the accommodation includes an aligner, and
the controller executes control to, in the transferring, before loading the second ring, load the replacement second ring accommodated in the accommodation into the aligner.

### (Appendix 18)

A method of transferring a ring in a substrate processing system that includes a plurality of processors each including a substrate support supporting a substrate and the ring disposed around the substrate, a vacuum transfer unit connected to the processors, the vacuum transfer unit including a transfer robot configured to transfer the substrate and the ring, and an accommodation configured to accommodate the ring, the transfer method including:
removing all the substrates from the processors and the vacuum transfer unit, and
after the removing, transferring the ring between at least one of the processors and the accommodation.

The invention is not limited to the configurations described in connection with the embodiment that has been described heretofore, or to the combinations of these configurations with other elements. Various variations and modifications may be made without departing from the scope of the present invention, and may be adopted according to applications. The aspects disclosed in the above embodiment also can have the other configurations to the extent not conflict, and can be combined with each other to the extent not conflict.

For example, the above embodiment has been described by taking a capacitively-coupled plasma apparatus as an example, but the present disclosure is not limited thereto and may be applied to other plasma apparatuses. For example, an inductively-coupled plasma (ICP) apparatus may be used instead of the capacitively-coupled plasma apparatus. In this case, the inductively-coupled plasma apparatus includes an antenna and a lower electrode. The lower electrode is disposed in the substrate support, and the antenna is disposed on an upper portion of or above a chamber. An RF generator is coupled to the antenna, and a DC generator is coupled to the lower electrode. Therefore, the RF generator is coupled to an upper electrode of the capacitively-coupled plasma apparatus or the antenna of the inductively-coupled plasma apparatus. That is, the RF generator is coupled to the plasma processing chamber 10.

1. A substrate processing system comprising:
a plurality of processors, each the processors including a substrate support supporting a substrate and a ring disposed around the substrate,
a vacuum transferer connected to the processors, the vacuum transferer including a transfer robot for transferring the substrate or the ring,
an accommodation for accommodating the ring, and
a controller configured to:
control the transfer robot to remove all the substrates from the processors and the vacuum transfer unit, and
after the removing, control the transfer robot to transfer the ring between at least one of the processors and the accommodation.

2. The substrate processing system according to claim 1, further comprising:
a vacuum reserve connected to the vacuum transferer, and
an atmospheric transferer connected to the vacuum transferer via the vacuum reserve, wherein
the controller is further configured to, in the removing, remove all the substrates from the vacuum reserve and the atmospheric transferer.

3. The substrate processing system according to claim 2, wherein
the controller is further configured to control the atmospheric transferer to, after the removing and before the transferring, load all the removed substrates into a substrate accommodation container.

4. The substrate processing system according to claim 2, wherein
the controller is further configured to control the atmospheric transferer to, after the removing and before the transferring, load all the removed substrates into a substrate accommodation container.

5. The substrate processing system according to claim 2, wherein
the accommodation includes a ring accommodation connected to the vacuum transferer.

6. The substrate processing system according to claim 5, wherein
the ring accommodation includes a first ring and a second ring disposed on the first ring, and
the controller is further configured to control the atmospheric transferer to, in the transferring, replace both the first ring and the second ring.

7. The substrate processing system according to claim 6, wherein
the controller is further configured to control the transfer robot to, in the transferring,
unload a used second ring from a first processor among the plurality of processors,
after unloading the second ring, unload the first ring from the first processor,
after unloading the first ring, load a replacement first ring into the first processor, and
after loading the replacement first ring, load a replacement second ring into the first processor.

8. The substrate processing system according to claim 7, wherein
the controller is further configured to control the transfer robot to, in the transferring,
load the second ring unloaded from the first processor into the ring accommodation, and
load the first ring unloaded from the first processor into the ring accommodation.

9. The substrate processing system according to claim 7, wherein
the accommodation includes an aligner, and
the controller is further configured to control the transfer robot to, in the transferring, before loading the replacement first ring accommodated in the accommodation, load the first ring into the aligner.

10. The substrate processing system according to claim 8, wherein
the accommodation includes an aligner, and
the controller is further configured to control the transfer robot to, in the transferring, before loading the first ring, load the replacement first ring accommodated in the accommodation into the aligner.

11. The substrate processing system according to claim 7, wherein
the accommodation includes an aligner, and
the controller is further configured to control the transfer robot to, in the transferring, before loading the replacement second ring accommodated in the accommodation, load the second ring into the aligner.

12. The substrate processing system according to claim 8, wherein
the accommodation includes an aligner, and
the controller is further configured to control the transfer robot to, in the transferring, before loading the second ring, load the replacement second ring accommodated in the accommodation into the aligner.

13. The substrate processing system according to claim 2, further comprising:
a load port connected to the atmospheric transferer, wherein
the accommodation includes a ring accommodation placed in the load port.

14. The substrate processing system according to claim 13, wherein
the ring accommodation includes a first ring and a second ring disposed on the first ring, and
the controller is further configured to control the atmospheric transferer to, in the transferring, replace the second ring without replacing the first ring.

15. The substrate processing system according to claim 14, wherein
the controller is further configured to control the transfer robot to, in the transferring,
unload the second ring from a first processor among the processors, and
load a replacement second ring into the first processor.

16. The substrate processing system according to claim 15, wherein
the controller is further configured to control the transfer robot to, in the transferring, load the second ring unloaded from the first processor into the ring accommodation.

17. The substrate processing system according to claim 15 wherein
the accommodation includes an aligner, and
the controller is further configured to control the transfer robot to, in the transferring, before loading the second ring, load the replacement second ring accommodated in the accommodation into the aligner.

18. A method of transferring, comprising:
by a controller, controlling a transfer robot of a vacuum transferer to remove substrates from a plurality of processors of a substrate processing system; and
after the removing, by the controller, controlling the transfer robot to transfer a ring of a substrate support of the substrate processing system between at least one of the processors and an accommodation of the substrate processing system.

19. The method of transferring according to claim 18, further comprising:
storing, by a ring accommodation of the substrate processing system, a first ring and a second ring, the second ring being disposed on the first ring; and
by the controller, controlling an atmospheric transferer of the substrate processing system to replace the first ring and the second ring.

20. The method of transferring according to claim 19, further comprising:
by the controller, controlling the transfer robot to,
unload the second ring from a first processor among the plurality of processors,
after unloading the second ring, unload the first ring from the first processor,
after unloading the first ring, load a replacement first ring into the first processor, and
after loading the first ring, load a replacement second ring into the first processor.
